(19) United States
(12) Patent Application Publication
(10) Pub. No.: US 2013/0241572 A1
(43) Pub. Date: Sep. 19, 2013

(54) SHIELD INSPECTION DEVICE AND SHIELD INSPECTION METHOD

(71) Applicant: FUJITSU LIMITED, Kawasaki-shi (JP)

(72) Inventors: Yoshihiro SAWADA, Inagi (JP); Kenji Nagase, Yokohama (JP); Yoshiaki Hiratsuka, Ota (JP); Tomoyuki Nakao, Yokohama (JP); Keisuke Nakamura, Tachikawa (JP)

(73) Assignee: FUJITSU LIMITED, Kawasaki-shi (JP)

(21) Appl. No.: 13/721,501

(22) Filed: Dec. 20, 2012

(30) Foreign Application Priority Data
Mar. 14, 2012 (JP) 2012-057904

(51) Int. Cl. G01R 29/08

(52) U.S. Cl. CPC G01R 29/0835
USPC 324/612

(57) ABSTRACT

A grouping unit groups closely arranged wirings to be protected from among a plurality of wirings to be protected by means of a shield and arranged on a circuit board. A division unit divides, for each of the grouped groups, a region around the group on the circuit board into a plurality of divided regions. A determination unit determines the existence of a shield for each of the divided regions.

### CROSS-REFERENCE TO RELATED APPLICATION

This application is based upon and claims the benefit of priority of the prior Japanese Patent Application No. 2012-057904, filed on Mar. 14, 2012, the entire contents of which are incorporated herein by reference.

### FIELD

The embodiment discussed herein is related to a shield inspection device and a shield inspection method.

### BACKGROUND

Internationally, electronic devices are required by laws to suppress a radiation noise of a high-speed signal and to improve durability against an exogenous noise. These two requirements are collectively referred to as electro-magnetic compatibility (EMC).

As effective measures in relation to the electro-magnetic compatibility, there is a shield technology of shielding a wiring to be protected where the radiation noise is suppressed and the durability against the exogenous noise is improved within a circuit board. The shield technology is a technology of covering a wiring. However, it is hard to cover all of the wirings because there are issues regarding a type of the wiring/arrangement of parts/a space for the wiring. Therefore, it is favorable that the electronic devices perform an inspection of whether the wiring to be protected is being properly shielded, considering the above-described issues.
Patent Literature 1: Japanese Laid-open Patent Publication No. 2011-18179
Patent Literature 2: Japanese Laid-open Patent Publication No. 2002-190573

However, it takes time to perform an inspection of the electro-magnetic compatibility with respect to all of regions around the wiring to be protected.

### SUMMARY

According to an aspect of an embodiment, a shield inspection device includes a grouping unit that groups a closely arranged wirings to be protected from among a plurality of wirings to be protected by means of a shield and arranged on a circuit board; a division unit that divides, for each of groups into which the wirings to be protected are grouped by the grouping unit, a region around the group on the circuit board into a plurality of divided regions; and a determination unit that determines existence of a shield for each of the divided regions divided by the division unit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an entire configuration of a shield inspection device;

FIG. 2 is a diagram illustrating an example of a setting screen;

FIG. 3 is a diagram illustrating a configuration example of net data;

FIG. 4 is a diagram illustrating an example of a wiring arranged on a circuit board;

FIG. 5 is a diagram for describing a method of calculating a parallel ratio;

FIG. 6 is a diagram illustrating an example of a result when a parallel net is obtained by obtaining, with respect to each of the wirings of Nets 1 to 10 illustrated in FIG. 4, a parallel ratio to an adjacent other wiring;

FIG. 7 is a diagram for describing a method of dividing a region to be divided;

FIG. 8 is a diagram illustrating an example of the divided region when one wiring to be protected constitutes a group;

FIG. 9 is a diagram illustrating an example of the divided region when a plurality of wirings to be protected constitutes a group;

FIG. 10 is a diagram for describing a method of specifying an invalid region of two wirings having portions arranged in parallel;

FIG. 11 is a diagram for describing a method of specifying an invalid region of two wirings having portions arranged to form an angle of 45 degrees;

FIG. 12 is a diagram for describing a method of specifying an invalid region of two wirings having portions arranged to form a certain angle;

FIG. 13 is a diagram illustrating an example of a result when a divided region in an invalid region is caused to be a region not to be determined;

FIG. 14 is a diagram for describing a method of specifying a prohibited region of a region on the circuit board, on which a device is arranged;

FIG. 15 is a diagram illustrating an example of determination of existence of a shield;

FIG. 16 is a diagram illustrating an example of a design screen;

FIG. 17 is a flowchart illustrating a procedure of a grouping process;

FIG. 18 is a flowchart illustrating a procedure of a parallel ratio calculation process;

FIG. 19 is a flowchart illustrating a procedure of an inspection process;

FIG. 20 is a flowchart illustrating a procedure of a shield pattern check process; and

FIG. 21 is a diagram for describing an example of a computer that executes a shield inspection program.

### DESCRIPTION OF EMBODIMENTS

Preferred embodiments of the present invention will be explained with reference to accompanying drawings. Note that these embodiments do not limit the technology of the disclosure. Also, each of the embodiments can be properly combined as long as contents of processes do not contradict each other.

### [a] First Embodiment

A configuration of a shield inspection device 10

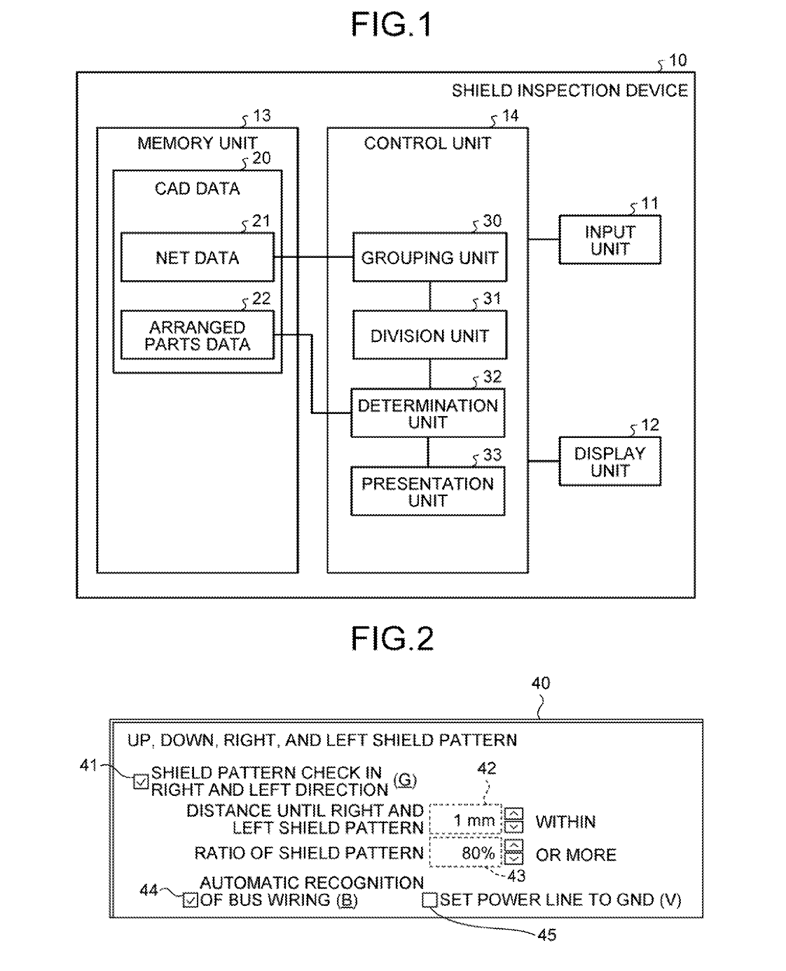

A shield inspection device according to a first embodiment will be described. FIG. 1 is a diagram illustrating an entire configuration of a shield inspection device. The shield inspection device 10 is a computer that performs an inspection of a shield state of a wiring arranged on a circuit board such as a print circuit board. The shield inspection device 10 may be a design device in which circuit design software for assisting a circuit design by a user operates, such as a computer aided design (CAD) device. As illustrated in FIG. 1, the shield inspection device 10 includes an input unit 11, a display unit 12, a memory unit 13, and a control unit 14.

The input unit 11 is an input device that inputs various types of information. An embodiment of the input unit 11 is an operation receiving device such as a mouse and a keyboard. The input unit 11 receives an input of the various types of information. For example, the input unit 11 receives, in designing a circuit, an instruction of arrangement of parts or a wiring on a circuit board to be designed from a user and inputs operation information that indicates the received operation content to the control unit 14.

The display unit 12 is a display device that displays various types of information. An embodiment of the display unit 12 is a display device such as a liquid crystal display (LCD) and a cathode ray tube (CRT). The display unit 12 displays the various types of information. For example, the display unit 12 displays a design screen used for arranging various parts and wirings on the circuit board and performing a circuit design. On this design screen, for example, the circuit board to be designed and the various parts and wiring to be arranged on the circuit board are displayed. Further, the display unit 12 displays a setting screen used for setting an inspection condition when the shield state of the wiring arranged on the circuit board is inspected. Further, when an error occurs, information in relation to the error is displayed on the display unit 12. For example, when an error such as insufficient shield of the arranged wiring occurs, information in relation to the occurred error is displayed on the design screen.

FIG. 2 is a diagram illustrating an example of the setting screen. As illustrated in FIG. 2, a setting screen 40 is provided with a check box 41 used for specifying whether a check of a shield pattern in a right and left direction of a wiring is performed. Further, the setting screen 40 is provided with an input region 42 used for inputting a reference value until right and left shield patterns, and an input region 43 used for inputting a ratio of a shield pattern that is determined to be shielded. Further, the setting screen 40 is provided with a check box 44 used for specifying whether a bus wiring is automatically recognized, and a check box 45 used for specifying whether a power line is also set to be a ground (GND).

When a user checks the shield state on the same layer of a wiring arranged on the circuit board, the user specifies the check box 41, inputs the reference value until the shield patterns to the input region 42, and inputs a ratio of a shield pattern that is determined to be shielded to the input region 43. Further, the user specifies the check box 44 when the automatic recognition of the bus wiring is specified at shield inspection. Further, the user specifies the check box 45 when the power line is also set to be the GND.

When the check box 41 is specified, the shield inspection device 10 inspects whether there is a shield within a distance of the reference value input to the input region 42 from the wiring. When there is a shield around the wiring at the ratio or more input to the input region 43, the shield inspection device 10 determines that the wiring is shielded. Further, the shield inspection device 10 performs, when the check box 44 is specified, a process of grouping a plurality of data wirings arranged in parallel at a shield check. Further, the shield inspection device 10 performs, when the check box 45 is specified, a shield check with having the power line as the GND.

Referring back to FIG. 1, the memory unit 13 is a memory device such as a semiconductor memory device like a flash memory, a hard disk, and an optical disk. Note that the memory unit 13 is not limited to the above-described types of memory devices and may be a random access memory (RAM) or a read only memory (ROM).

The memory unit 13 stores various programs such as an operating system (OS) executed in the control unit 14, a design assistance program used in circuit design, and a program used for a shield inspection described below. Further, the memory unit 13 stores various types of data. As an example of the data, the memory unit 13 stores CAD data 20.

The CAD data 20 is data in which various types of information in relation to a designed circuit are stored. The CAD data 20 includes, as data that relates to the present embodiments, net data 21 and arranged parts data 22. The net data 21 is data in which various types of information in relation to a wiring such as an arranged position of the wiring arranged on the circuit board and the type of the wiring are stored. As an example, the net data 21 is referenced by a grouping unit 30 described below in order to perform an inspection regarding the shield state of the wiring arranged on the circuit board. The arranged parts data 22 is data in which various types of information in relation to parts such as an arranged position of the parts arranged on the circuit board and the type of the parts are stored. As an example, the arranged parts data 22 is referenced by a determination unit 32 described below in order to set a region not to be inspected of shield.

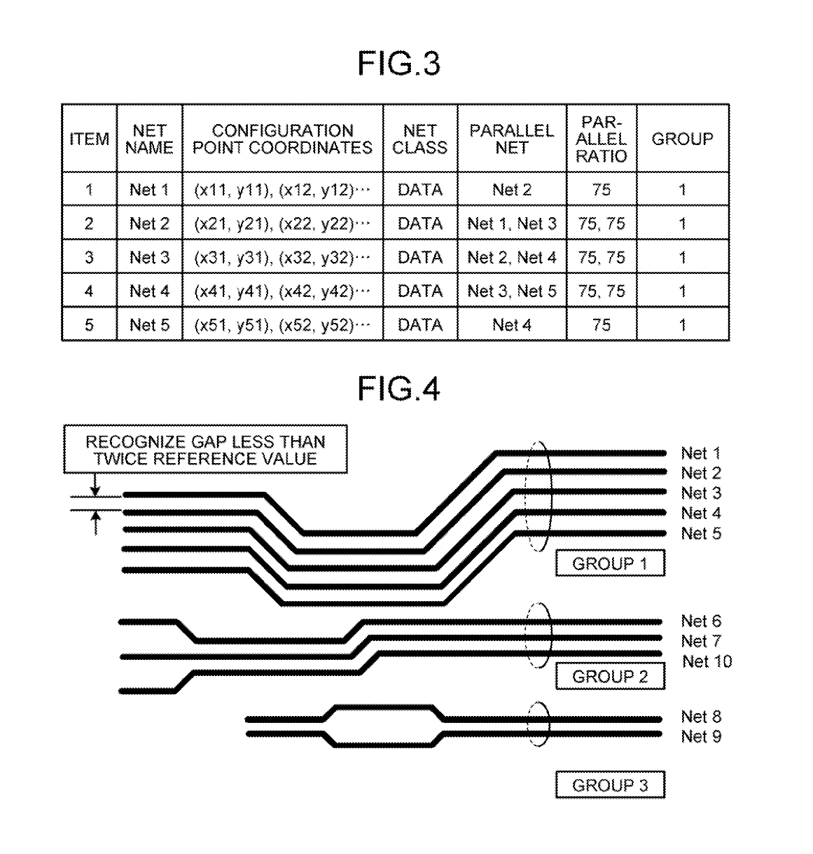

FIG. 3 is a diagram illustrating a configuration example of the net data. As illustrated in FIG. 3, the net data 21 has items including “item number”, “net name”, “configuration point coordinates”, “net class”, “parallel net”, “parallel ratio”, and “group”. The item of “item number” is a region in which a number assigned to each wiring is stored. In the present embodiment, the number is assigned in ascending order as the item number. The item of “net name” is a region in which a name of a net indicating each wiring is stored. The item of “configuration point coordinates” is a region in which a position of coordinates of configuration points on the circuit board through which the wiring passes such as an end point of the wiring and a change point at which the direction of the wiring changes are stored. The wiring is arranged on the circuit board by combining line segments. The coordinates of both end points of the line segments that constitute the wiring are stored in the item of “configuration point coordinates” as configuration point coordinates. The item of “net class” is a region in which a class of the wiring such as the type of data transmitted in the wiring is stored. Information indicating the class of the wiring such as a data wiring, a clock wiring, and a reset wiring is stored in the item of “net class”. The “data” stored in the net class indicates that the data is the data wiring. The item of “parallel net” is a region in which a net name of other wiring arranged in parallel with the wiring is stored. The item of “parallel ratio” is a region in which a value indicating a parallel ratio of other wiring being arranged in parallel is stored. The item of “group” is a region in which identification information of a group to which the wiring belongs when the wiring is grouped is stored. Information of each item of “item number”, “net name”, “configuration point coordinates”, and “net class” is registered in designing a circuit. Information of each item of “parallel net”, “parallel ratio”, and “group” is registered by the grouping unit 30 described below.

In the example of FIG. 3, a wiring of the item number “1” indicates that the net name is “Net 1”, the coordinates of configuration point are (x11, y11), (x12, y12), . . . , and the net class is “data”. Also, the wiring of the item number “1” indicates that the parallel net is “Net 2”, the parallel ratio to Net 2 is “75”%, and the group is “1”. Further, a wiring of the item number “2” indicates that the net name is “Net 2”, the coordinates of configuration point are (x21, y21), (x22, y22), . . . , and the net class is “data”. Also, the wiring of the item number “2” indicates that the parallel net is “Net 1” and “Net 3”, the parallel ratio to Net 1 is “75”%, the parallel ratio to Net 3 is “75”%, and the group is “1”. Also, the wiring of the item number “3” indicates that the net name is “Net 3”, the coordinates of configuration point are (x31, y31), (x32, y32), . . . , and the net class is “data”. Further, a wiring of the item number “3” indicates that the parallel net is “Net 2” and “Net 4”, the parallel ratio to Net 2 is “75”%, the parallel ratio to Net 4 is “75”%, and the group is “1”. Further, a wiring of the item number “4” indicates that the net name is “Net 4”, the coordinates of configuration point are (x41, y41), (x42, y42), . . . , and the net class is “data”. Also, the wiring of the item number “4” indicates that the parallel net is “Net 3” and “Net 5”, the parallel ratio to Net 3 is “75”%, the parallel ratio to Net 5 is “75”%, and the group is “1”. Further, a wiring of the item number “5” indicates that the net name is “Net 5”, the coordinates of configuration point are (x51, y51), (x52, y52), . . . , and the net class is “data”. Also, the wiring of the item number “5” indicates that the parallel net is “Net 4”, the parallel ratio to Net 4 is “75”%, and the group is “1”.

Referring back to description of FIG. 1, the control unit 14 is a control device that controls the entire device. An embodiment of the control unit 14 is an electronic circuit such as a central processing unit (CPU) and a micro processing unit (MPU). The control unit 14 has an internal memory for storing a program that defines a procedure of various processes and control data, and executes various processes with these program and data. The control unit 14 has, as illustrated in FIG. 1, the grouping unit 30, a division unit 31, the determination unit 32, and a presentation unit 33.

The grouping unit 30 is a processing unit that groups the wirings arranged on the circuit board. As an embodiment, the grouping unit 30 identifies a wiring to be protected from among the wirings arranged on the circuit board. For example, the clock wiring through which a clock signal is transmitted may generate a radiation noise and the clock signal may be disturbed due to an exogenous noise. Therefore, it is favorable to protect the clock wiring by a shield in order to suppress the radiation noise and the generation of disturbance of the clock signal due to the exogenous noise. Also, the data wiring through which a data signal is transmitted may generate a radiation noise and the data signal may be disturbed due to an exogenous noise. Therefore, it is favorable to protect the data wiring by a shield in order to suppress the radiation noise and the generation of disturbance of the data signal due to the exogenous noise. Further, the reset wiring through which a reset signal is transmitted may be subject to disturbance of the reset signal due to an exogenous noise and may be reset. Therefore, it is favorable to protect the reset wiring by a shield in order to suppress the generation of disturbance of the reset signal due to the exogenous noise. In the present embodiment, the clock wiring, the data wiring, and the reset wiring are the wirings to be protected. Note that other wirings that are favorably expected to suppress the radiation noise or the generation of disturbance of a signal due to the exogenous noise may be the wirings to be protected. The grouping unit 30 references the item of net class of the net data 21 with respect to each of the wirings arranged on the circuit board, and identifies whether the wiring is the wiring to be protected from the type of transmitted data.

The grouping unit 30 groups the wirings to be protected that are closely arranged each other from among a plurality of wirings to be protected. For example, the grouping unit 30 obtains, with respect to each of the wirings to be protected, a parallel ratio of being parallel with an adjacent other wiring with a gap less than a predetermined distance, and groups the wirings to be protected in such a way that the wirings to be protected having the ratio that is a predetermined value or more can belong to the same group. In the present embodiment, this predetermined distance is twice the reference value input to the input region 42 on the setting screen 40. In the present embodiment, the grouping unit 30 obtains, with respect to each of the wirings to be protected, the parallel ratio of being parallel with an adjacent other wiring to be protected with a gap less than twice the reference value. For example, when the reference value input to the input region 42 on the setting screen 40 is 1 mm, the grouping unit 30 obtains the parallel ratio of being parallel with a gap less than 2 mm. Note that, in the present embodiment, the predetermined distance is a value of twice the reference value. However, the predetermined value may be able to be set on the setting screen 40 and the like other than the reference value. Also, the predetermined distance may be a fixed value.

By the way, regarding a bus wiring, a plurality of bus wirings simultaneously transmits a plurality of bits, and the plurality of bus wirings is arranged in parallel. Also, a differential signal wiring transmits a signal by causing two wirings to transmit opposite-phase signals, and the two wirings are arranged in parallel. That is, regarding the wiring through which data is transmitted, a plurality of wirings is arranged in parallel. Meanwhile, a wiring through which a clock signal or a reset signal is transmitted is often arranged alone. In the present embodiment, the wiring to be protected through which data is transmitted is grouped with a closely arranged wiring to be protected. Meanwhile, the wiring to be protected through which the clock signal or the reset signal is transmitted is grouped alone to constitute a group. Also, in the present embodiment, whether the wiring to be protected through which data is transmitted is grouped can be specified by the check box 44 on the setting screen 40. In the present embodiment, when the check box 44 on the setting screen 40 is specified, the grouping unit 30 groups the wiring to be protected with a closely arranged wiring to be protected.

Here, a specific example of grouping a wiring arranged on a circuit board will be described. FIG. 4 is a diagram illustrating an example of a wiring arranged on a circuit board. In the example illustrated in FIG. 4, the wirings of Nets 1 to 10 are arranged on the circuit board. The grouping unit 30 obtains, with respect to each of the wirings of Nets 1 to 10, a parallel ratio of being parallel with an adjacent other wiring with a gap less than twice the reference value.

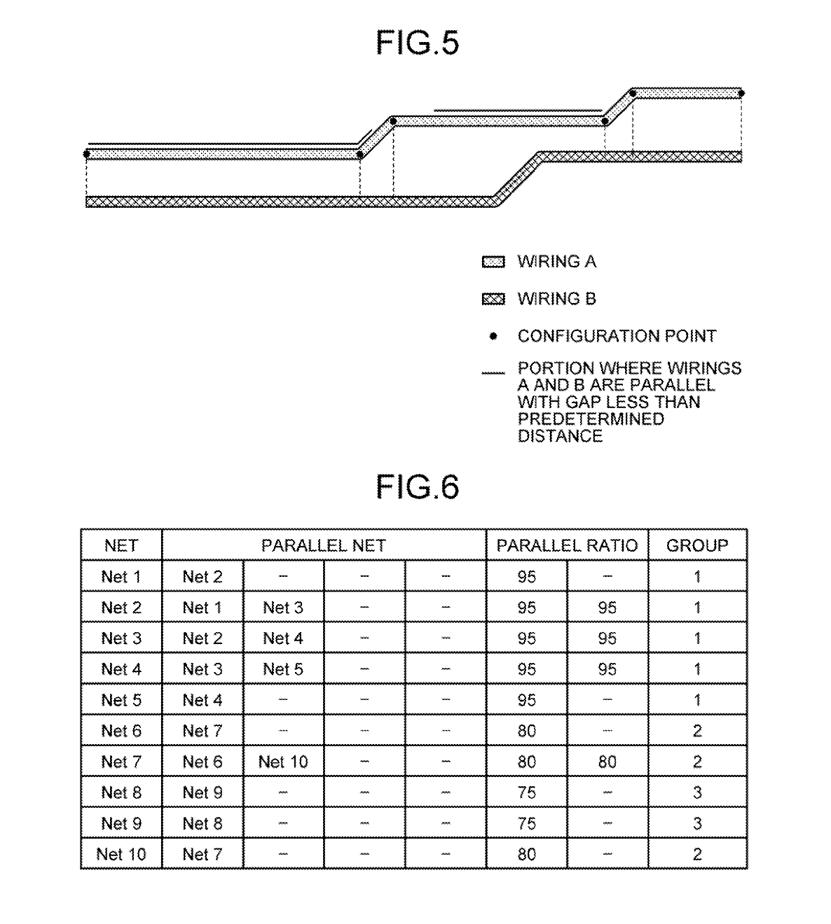

FIG. 5 is a diagram for describing a method of calculating the parallel ratio. For example, when the ratio of the two wirings A and B illustrated in FIG. 5 being parallel is obtained, the grouping unit 30 draws a perpendicular line from a configuration point (x, y coordinate) that constitutes the wiring A to the wiring B. The grouping unit 30 specifies the configuration point as a target configuration point because the wirings are parallel within a range of the configuration point when the length of the perpendicular line is less than twice the reference value. Note that the grouping unit 30 determines whether the perpendicular line having the shortest length has a length less than twice the reference value when a plurality of perpendicular lines can be drawn from the configuration point that constitutes the wiring A to the wiring B.

The grouping unit 30 obtains the length of the perpendicular line with respect to each configuration point of the wirings and specifies the target configuration point. Then, the grouping unit 30 causes the parallel ratio of a portion of the wiring having the target configuration point at the both ends to be 100% when the configuration points at both ends are the target configuration point. Also, the grouping unit 30 calculates the ratio using the proportion of the length of the perpendicular line to twice the reference value when the configuration point of one of the both ends is the target point. For example, when the lengths of the perpendicular lines from the configuration point are 0.8 mm and 1.2 mm, respectively, and the reference value is 0.5 mm, the parallel ratio of being parallel with a distance less than 1.0 mm, which is twice the reference value, is 50%. Also, the grouping unit 30 causes the parallel ratio to be 0% when the configuration points at the both ends are not the target configuration point. In this way, the grouping unit 30 calculates the parallel ratio, with respect to each wiring, by the length of the portion parallel with an adjacent wiring to the length of the entire wiring.

The grouping unit 30 specifies the wiring having the parallel ratio of the predetermined value or more as a parallel wiring. In the present embodiment, the parallel ratio of, for example, 50% or more is the parallel wiring. Then, the grouping unit 30 groups the wirings such that the parallel wirings belong to the same group. Note that, in the present embodiment, the predetermined value is a fixed value. However, the predetermined value can be set on the setting screen 40.

FIG. 6 is a diagram illustrating an example of a result when a parallel net is obtained by obtaining the parallel ratio of being parallel with an adjacent other wiring with respect to each of the wirings of Nets 1 to 10 illustrated in FIG. 4. In the example of FIG. 6, the wiring of “Net 1” indicates that the parallel ratio to the wiring of “Net 2” is 95%. Further, the wiring of “Net 2” indicates that the parallel ratio to the wiring of “Net 1” is 95%, and the parallel ratio to the wiring to “Net 3” is 95%. Further, the wiring of “Net 3” indicates that the parallel ratio to the wiring of “Net 2” is 95%, and the parallel ratio to the wiring of “Net 4” is 95%. Further, the wiring of “Net 4” indicates that the parallel ratio to the wiring of “Net 3” is 95%, and the parallel ratio to “Net 5” is 95%. Further, the wiring of “Net 5” indicates that the parallel ratio to the wiring of “Net 4” is 95%. Further, the wiring of “Net 6” indicates that the parallel ratio to the wiring of “Net 7” is 80%. Further, the wiring of “Net 7” indicates that the parallel ratio to the wiring of “Net 6” is 80%, and the parallel ratio to the wiring of “Net 10” is 80%. Further, the wiring of “Net 8” indicates that the parallel ratio to the wiring of “Net 9” is 75%. Further, the wiring of “Net 9” indicates that the parallel ratio to the wiring of “Net 8” is 75%. Further, the wiring of “Net 10” indicates that the parallel ratio to the wiring of “Net 7” is 80%.

The example of FIG. 6 illustrates a result of grouping the wirings having the parallel ratio of 50% and more so that the wirings can belong to the same group. As illustrated in FIGS. 4 and 6, the wirings of Nets 1 to 5 are grouped into a group of the number “1”, the wirings of Nets 6, 7, and 10 are grouped into a group of the number “2”, and the wirings of Nets 8 and 9 are grouped into a group of the number “3”.

The grouping unit 30 registers, with respect to each wiring, the obtained parallel ratio, the other parallel wirings, and the belonged group on the net data 21.

The division unit 31 divides a region around the group on the circuit board into a plurality of divided regions for each of the groups into which the wirings to be protected are grouped. As an embodiment, the division unit 31 divides a region at a predetermined distance outside from the wiring to be protected belonged to the group and positioned at an outermost side of the group into a plurality of divided regions.

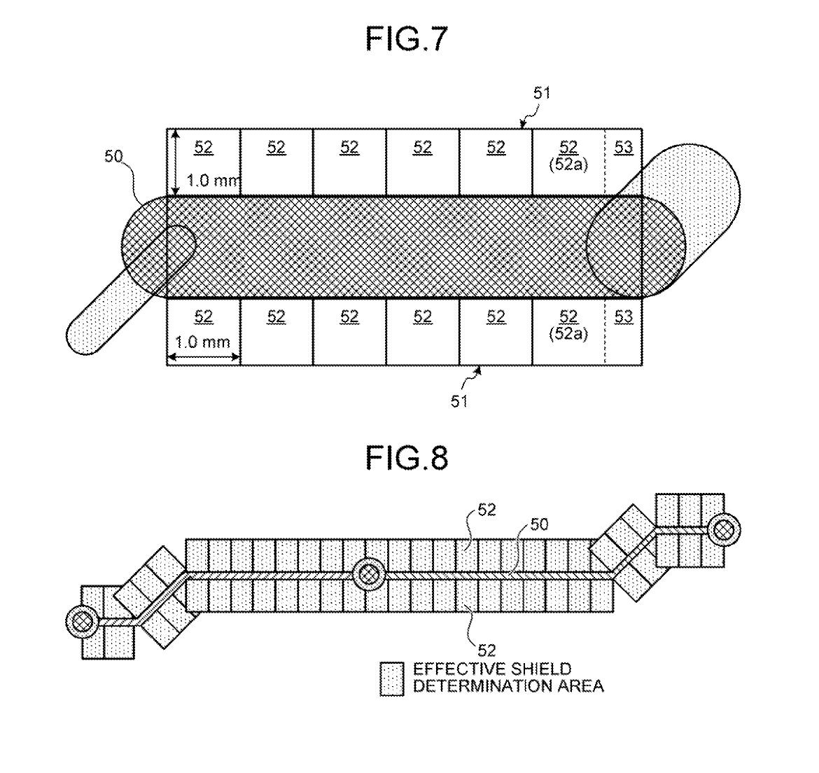

FIG. 7 is a diagram for describing a method of dividing a region to be divided. For example, the division unit 31 obtains a region by offsetting the reference value outward (in a width direction of the wiring) from an outer peripheral line segment of the wiring to be protected belonged to the group and positioned at an outermost side of the group. In an example of FIG. 7, the reference value is 1.0 mm, and a region 51 is obtained by offsetting the wiring to be protected 50 by 1.0 mm. Then, the division unit 31 divides the region 51 in a line direction of the wiring to be protected 50 to create a divided region 52. In the example of FIG. 7, the region 51 is divided into a square having the width of 1.0 mm that is the same as the reference value in order to form the divided region 52 to be a square and the divided region 52 is created. However, the width to be divided may be set on the setting screen 40. The division unit 31 synthesizes a remaining portion 53 with the nearest divided region 52 when there is a remaining portion having an insufficient width at dividing the region 51 by the width of 1.0 mm. In the example of FIG. 7, the remaining portion 53 is synthesized with a neighbor divided region 52a.

FIG. 8 is a diagram illustrating an example of a divided region when one wiring to be protected constitutes a group. The example of FIG. 8 is a case where the wiring to be protected 50 constitutes a group. In the example of FIG. 8, the divided region 52 is created around the wiring to be protected 50. Note that FIG. 8 illustrates the divided region 52 that is a region to be determined regarding the existence of a shield as an effective shield determination area.

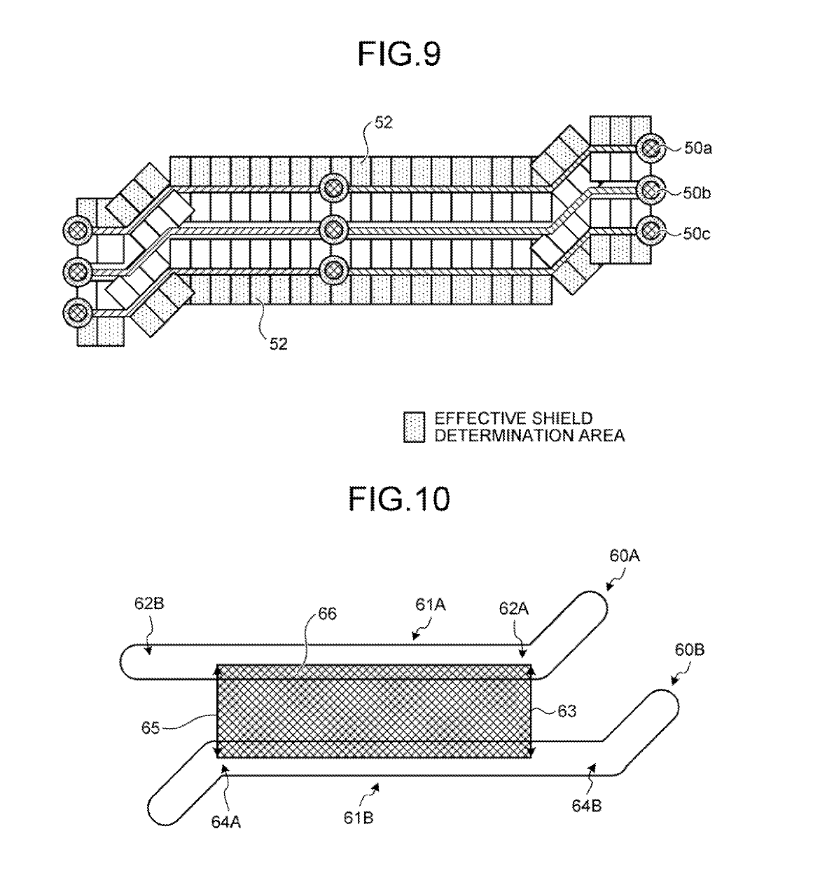

FIG. 9 is a diagram illustrating an example of a divided region when a plurality of wirings to be protected constitutes a group. An example of FIG. 9 illustrates three wirings to be protected 50a to 50c constitute a group. In the example of FIG. 9, the divided region 52 is created at an upper part of the wiring to be protected 50a and at a lower part of the wiring to be protected 50c. Note that FIG. 9 illustrates the divided region 52 that is a region to be determined regarding the existence of a shield as an effective shield determination area. Also, FIG. 9 illustrates an example where regions between the wirings to be protected 50a and 50b, and 50b and 50c are divided. However, because the regions between the wirings to be protected 50a and 50b, and 50b and 50c are the regions not to be determined regarding the existence of a shield, the regions are not necessary to be divided into divided regions.

Referring back to FIG. 1, the determination unit 32 determines the existence of a shield for each divided region. As an embodiment, the determination unit 32 determines that there is a shield when a conductor or a power line connected to a ground (GND) exists on the divided region, whilst, the determination unit 32 determines that there is not a shield when the conductor or the power line does not exist. Also, in the present embodiment, whether the power line is shielded can be specified by the check box 45 on the setting screen 40. In the present embodiment, the determination unit 32 determines, when the check box 45 on the setting screen 40 is specified, whether the conductor or the power line connected to the ground exists at a predetermined ratio or more on the divided region. Also, the determination unit 32 determines, when the check box 45 on the setting screen 40 is not specified, whether the conductor connected to the ground exists on the divided region at the predetermined ratio.

By the way, there is a region on the circuit board where it is hard to arrange a shield. For example, it may sometimes be hard to arrange a shield on a portion where a distance between the wirings is less than twice the reference value. Also, it may sometimes be hard to arrange a shield on a region on the circuit board where a device such as an integrated circuit (IC) is arranged because a connection wiring for connecting with the device is provided.

Therefore, the determination unit 32 allows a divided region within a region where it is hard to arrange a shield to be a region not to be determined. As an embodiment, the determination unit 32 specifies, when there is a portion having a distance from each configuration point of the wiring to an adjacent wiring of less than twice a specified reference value, an invalid region that is to be a region not to be determined from among an area between the wirings, which has a distance less than twice the reference value. Then, the determination unit 32 allows a divided region within the invalid region to be the region not to be determined. Further, as another embodiment, the determination unit 32 specifies a region on the circuit board where a device such as an IC is arranged as a prohibited region. Then, the determination unit 32 allows a divided region within the prohibited region to be the region not to be determined.

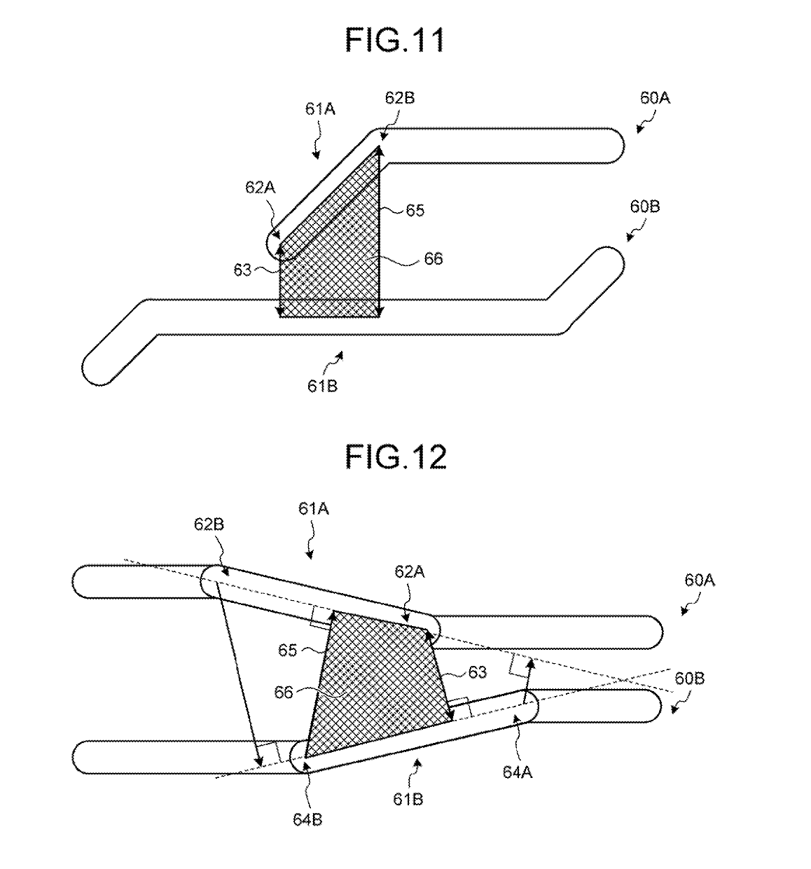

FIGS. 10 to 12 are diagrams for describing a method of specifying an invalid region between wirings. Note that FIG. 10 is a diagram for describing a method of specifying two wirings having portions arranged in parallel. FIG. 11 is a diagram for describing a method of specifying an invalid region of two wirings having portions arranged to form an angle of 45 degrees. FIG. 12 is a diagram for describing a method of specifying an invalid region of two wirings having portions arranged to form a certain angle.

The determination unit 32 specifies an invalid region by performing the following process for each line segment that constitutes a straight line of a wiring. Note that, hereinafter, for the purpose of simplifying the process, a case will be described where an invalid region is determined between a line segment A of a wiring A and a line segment B of a wiring B that face each other, the wirings A and B being adjacent to each other. The determination unit 32 draws perpendicular lines from both end points of the line segment A of the wiring A to the line segment B of the wiring B. The determination unit 32 obtains a distance between the line segments A and B along the perpendicular lines when the perpendicular line from each of the end points of the line segment A passes through the line segment B. The determination unit 32 specifies a region surrounded by the line segments A and B and the two perpendicular lines as an invalid region when each of the perpendicular lines from the both end points of the line segment A passes through the line segment B, and the distance along at least one of the perpendicular lines is less than twice the reference value.

Meanwhile, the determination unit 32 draws perpendicular lines from both end points of the line segment B to the line segment A when the distance between the line segments A and B along a perpendicular line from only one of the end points of the line segment A is less than twice the reference value. Then, the determination unit 32 specifies a region surrounded by a perpendicular line that passes through the line segment A from the perpendicular lines from the both end points of the line segment B to the line segment A, a perpendicular line from one of the end points of the line segment A, and the line segments A and B as an invalid region.

In an example of FIG. 10, when perpendicular lines are drawn from both end points 62A and 62B of a line segment 61A of a wiring 60A to a line segment 61B of a wiring 60B, only a perpendicular line 63 from the end point 62A passes through the line segment 61B, and the distance is less than twice the reference value. In the example of FIG. 10, perpendicular lines are drawn from end points 64A and 64B of the line segment 61B to the line segment 61A, and a region 66 surrounded by a perpendicular line 65 that passes through the line segment 61A, the perpendicular line 63 from the end point 62A of the line segment 61A, and the line segments 61A and 61B is specified as an invalid region.

Further, in an example of FIG. 11, when perpendicular lines are drawn from both end points 62A and 62B of a line segment 61A of a wiring 60A to a line segment 61B of a wiring 60B, respective perpendicular lines 63 and 65 from the end points 62A and 62B pass through the line segment 61B, and the distance along the perpendicular line 63 is less than twice the reference value. In the example of FIG. 11, a region 66 surrounded by the line segments 61A and 61B, and the perpendicular lines 63 and 65 is specified as an invalid region.

Also, in an example of FIG. 12, when perpendicular lines are drawn from both end points 62A 62B of a line segment 61A of a wiring 60A to a line segment 61B of a wiring 60B, only a perpendicular line 63 from the end point 62A passes through the line segment 61B, and the distance is less than twice the reference value. In the example of FIG. 12, perpendicular lines are drawn from end points 64A and 64B of the line segment 61B to the line segment 61A, and a region 66 surrounded by a perpendicular line 65 that passes through the line segment 61A, the perpendicular line 63 of the end point 62A of the line segment 61A, and the line segments 61A and 61B is specified as an invalid region.

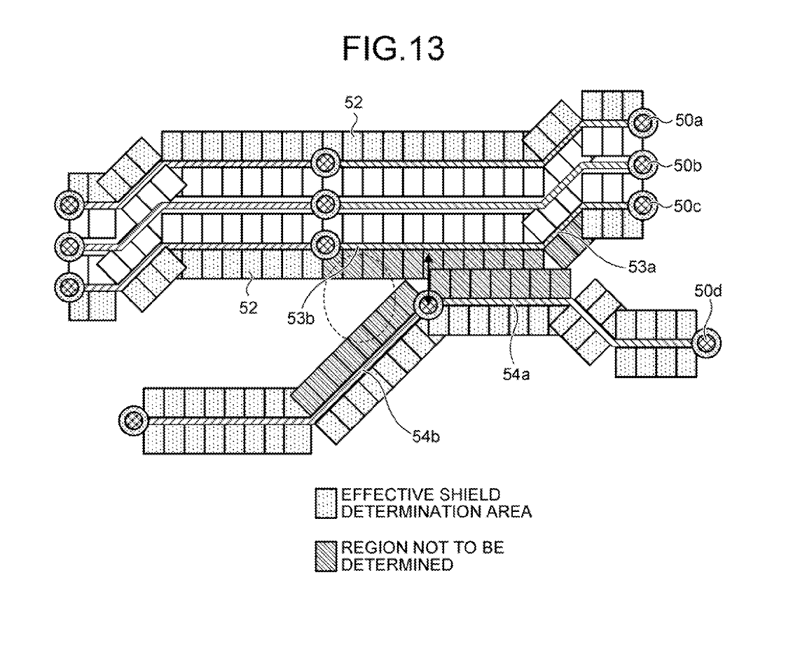

The determination unit 32 causes a divided region within the specified invalid region to be a region not to be determined. FIG. 13 is a diagram illustrating an example of a result of causing a divided region within the invalid region to be a region not to be determined. An example of FIG. 13 illustrates a case where a wiring to be protected 50d adjacent to the wirings to be protected 50a to 50c of FIG. 9 is arranged. The example of FIG. 13 illustrates a result where the invalid region between the wirings to be protected 50c and 50d is specified. In the example of FIG. 13, a divided region 52 of line segments 53a and 53b of the wiring to be protected 50c and a divided region 52 of line segments 54a and 54b of the wiring to be protected 50d are regions not to be determined, respectively.

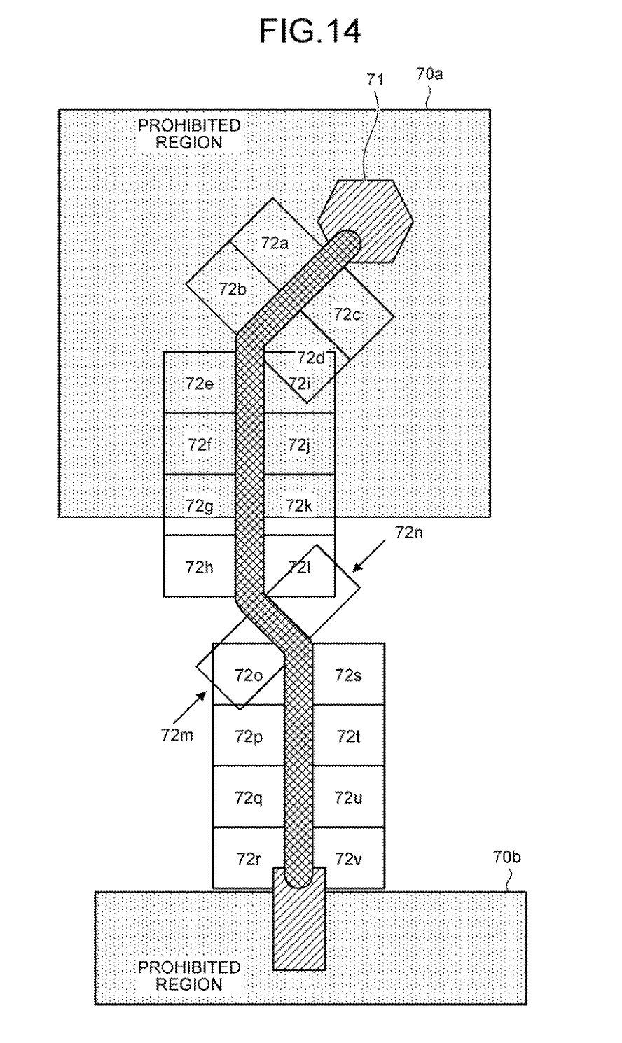

FIG. 14 is a diagram for describing a method of specifying a prohibited region of a region on the circuit board where a device is arranged. The determination unit 32 specifies a region on the circuit board where parts are arranged as a prohibited region based on the arranged parts data 22, and performs determination having a divided region within the prohibited region as a region not to be determined. In an example of FIG. 14, prohibited regions 70a and 70b are specified by the parts arranged on the circuit board, and divided regions 72a to 72g, and 72i to 72k within the prohibited region 70a from among divided regions 72a to 72v of a wiring to be protected 71 are regions not to be determined.

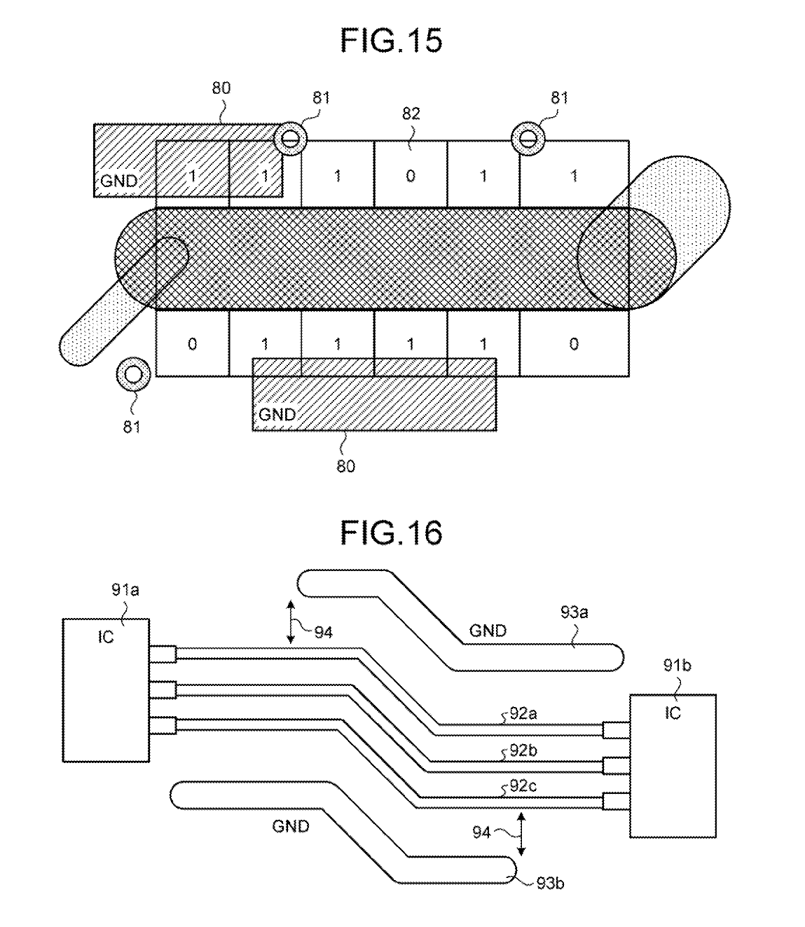

The determination unit 32 determines the existence of a shield for each divided region of each wiring to be protected except the divided region not to be determined. In the present embodiment, it is determined, when a conductor or a power line connected to a ground overlaps with a divided region if only a little, that there is a shield on the divided region. FIG. 15 is a diagram illustrating an example of determination of the existence of a shield. In an example of FIG. 15, the number “1” that indicates there is a shield is illustrated on a divided region 82 on which any one of a wiring 80 connected to a ground or a via 81 connected to a ground is arranged, and the number “0” that indicates there is not a shield is illustrated on the divided region 82 on which none of the wiring 80 and the via 81 is arranged.

The determination unit 32 obtains, for each wiring to be protected, a ratio of being shielded from the total number of divided regions determined to be shielded except a divided region determined to be a region not to be determined to the total number of effective divided regions.

The presentation unit 33 presents, as a result of the determination by the determination unit 32, a portion on the circuit board determined to be insufficiently shielded. As an embodiment, when there is a group of the wirings to be protected having the ratio obtained by the determination unit 32 that is less than the ratio input to the input region 43 on the setting screen 40, the grouping unit 30 presents a mark indicating an insufficient shield on a position of the wiring to be protected of the group on the design screen. Note that the presentation unit 33 may present, as a result of the determination by the determination unit 32, a portion on the circuit board determined to be insufficiently shielded with character information and the like.

FIG. 16 is a diagram illustrating an example of a design screen. In the example of FIG. 16, two ICs 91a and 91b are connected by three wirings 92a to 92c, and ground wirings 93a and 93b connected to a ground are provided around the wirings 92a to 92c. The example of FIG. 16 lacks a region where the ground wirings 93a and 93b are arranged, and a mark 94 that indicates an insufficient shield is presented.

When there is an insufficient shield, a designer is presented a portion determined to be insufficiently shielded with the mark 94, thereby recognizing an insufficiently shielded wiring, and correcting the insufficient shield.

A flow of the process

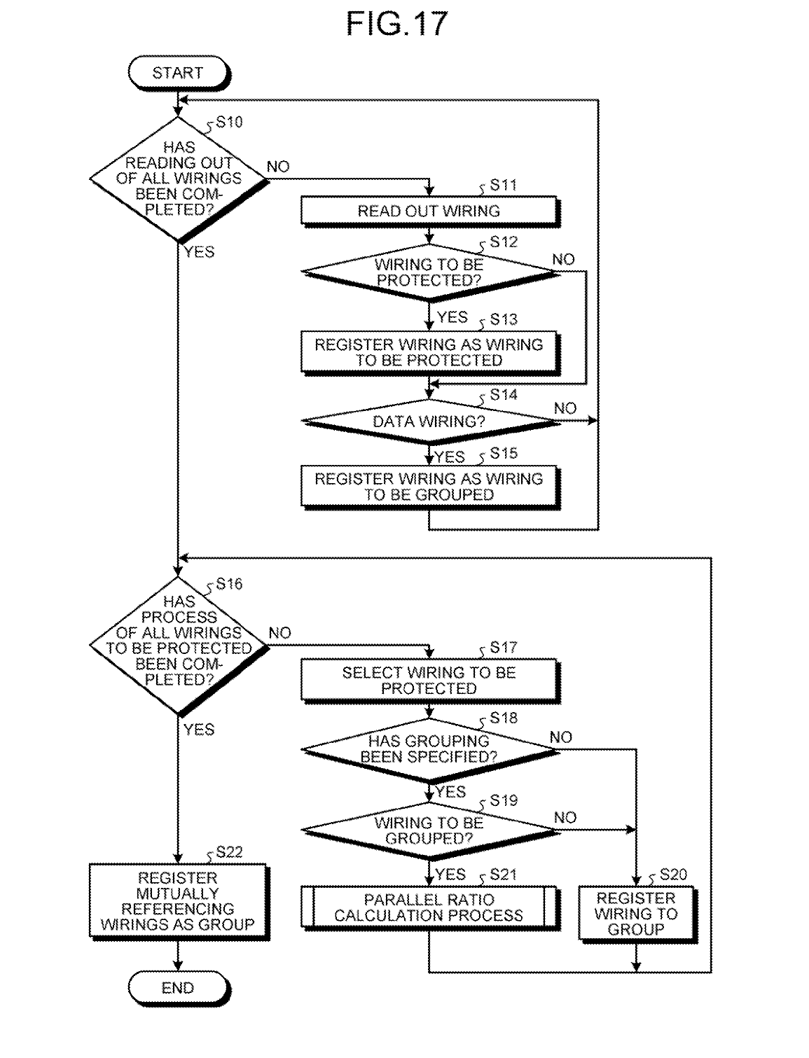

Next, a flow of s process of the shield inspection device 10 according to the present embodiment will be described. FIG. 17 is a flowchart illustrating a procedure of a grouping process. This grouping process is executed when a predetermined operation that instructs a start of an inspection is performed. Note that the grouping process may be executed following a particular process executed in designing a circuit.

As illustrated in FIG. 17, the grouping unit 30 determines whether reading out of data of all of the wirings from the net data 21 has been completed (step S10). The grouping unit 30 reads out, when the data of all of the wirings has not been read out (No at step S10), the data of the wirings from the net data 21 (step S11). The grouping unit 30 determines whether the read out wiring is the class of the wiring to be protected based on a class of the read out wiring (step S12). When the class of the read out wiring is the class of the wiring to be protected (Yes at step S12), the grouping unit 30 registers the read out wiring as the wiring to be protected (step S13). Meanwhile, the class of the read out wiring is not the class of the wiring to be protected (No at step S12), the grouping unit 30 proceeds to step S14 described below.

The grouping unit 30 determines whether the read out wiring is the data wiring (step S14). When the read out wiring is the data wiring (Yes at step S14), the grouping unit 30 registers the read out wiring as the wiring to be grouped (step S15), and proceeds to step S10. Meanwhile, the read out data is not the data wiring (No at step S14), the grouping unit 30 proceeds to step S10.

When the data of all of the wirings has been read out (Yes at step S10), the grouping unit 30 determines whether the process for all of the wirings to be protected has been completed (step S16). When the process for all of the wirings to be protected has not been completed (No at step S16), the grouping unit 30 selects any one of unprocessed wirings to be protected (step S17). The grouping unit 30 determines whether grouping of the wirings to be protected is specified by the check box 44 on the setting screen 40 (step S18). When the grouping is not specified (No at step S18), the grouping unit 30 proceeds to step S20 described below. Meanwhile, when the grouping is specified (Yes at step S18), the grouping unit 30 determines whether the selected wiring to be protected is the wiring to be grouped (step S19). When the selected wiring to be protected is not the wiring to be grouped (No at step S19), the grouping unit 30 registers the wiring to be protected alone to a group (step S20), and proceeds to step S16. Meanwhile, when the wiring to be protected is the wiring to be grouped (Yes at step S19), the grouping unit 30 executes a parallel ratio calculation process (step S21), and proceeds to step S16 when the parallel ratio calculation process is completed.

When the process for all of the wirings to be protected has been completed (Yes at step S16), the grouping unit 30 groups the wirings mutually arranged in parallel into the same group (step S22), and terminates the process.

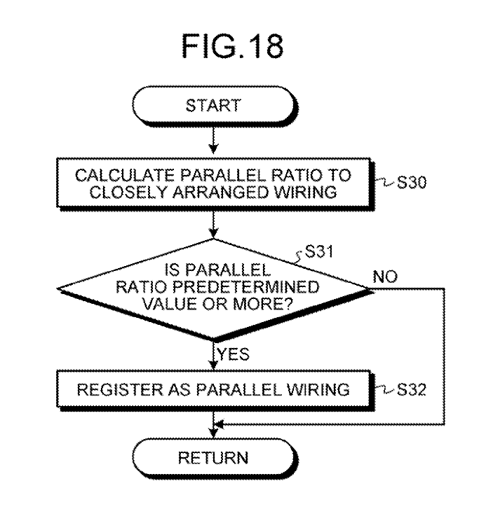

Next, a flow of the parallel ratio calculation process according to the present embodiment will be described. FIG. 18 is a flowchart illustrating a procedure of the parallel ratio calculation process. This parallel ratio calculation process is executed upon being called by step S21 of the grouping process illustrated in FIG. 17.

As illustrated in FIG. 18, the grouping unit 30 calculates, with respect to the wirings to be protected that are determined to be the wirings to be grouped, a parallel ratio of being parallel with a closely arranged other wiring to be protected (step S30). The grouping unit 30 determines whether the calculated parallel ratio is a predetermined value or more (step S31). When the parallel ratio is the predetermined value or more (Yes at step S31), the grouping unit 30 registers the closely arranged other wiring to be protected as a parallel wiring (step S32), and terminates the process. Meanwhile, when the parallel ratio is not the predetermined value or more (No at step S31), the grouping unit 30 terminates the process.

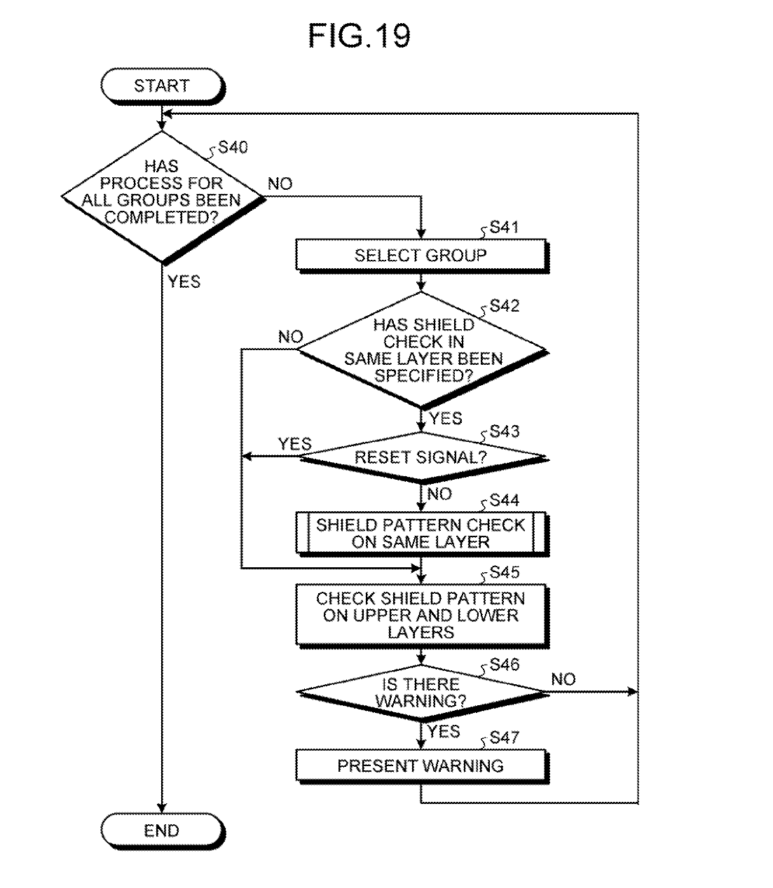

Next, a flow of an inspection process for inspecting a shield state of a wiring arranged on a circuit board by the shield inspection device 10 according to the present embodiment will be described. FIG. 19 is a flowchart illustrating a procedure of the inspection process. This inspection process is executed following the above-described grouping process when a predetermined operation that instructs a start of an inspection is performed. Note that the inspection process may be executed following a particular process executed in designing a circuit as long as the inspection process is executed after the grouping process.

As illustrated in FIG. 19, the determination unit 32 determines whether the process for the groups of all of the grouped wirings to be protected has been completed (step S40). When the process for the groups of all of the wirings to be protected has been completed (Yes at step S40), the determination unit 32 terminates the process. Meanwhile, when the process for the groups of all of the wirings to be protected has not been completed (No at step S40), the determination unit 32 selects any one of unprocessed groups of the wirings to be protected (step S41). The determination unit 32 determines whether a check of a shield pattern of the same wiring layer as the wiring to be protected has been specified by the check box 41 on the setting screen 40 (step S42). In this way, the shield inspection device 10 is capable of switching between the check of the shield pattern of the same wiring layer is performed and not performed in accordance with the existence of the input to the check box 41 on the setting screen 40. Therefore, according to the shield inspection device 10, a processing load of the shield inspection can be relieved by not specifying the check of the shield pattern by the check box 41 on the setting screen 40 when the shield pattern on the same wiring layer is not necessary.

When the check of the shield pattern on the same wiring layer is not specified (No at step S42), the determination unit 32 proceeds to step S45 described below. Meanwhile, the check of the shield pattern on the same wiring layer is specified (Yes at step S42), the determination unit 32 determines whether the wiring to be protected of the group is the wiring of the reset signal (step S43). Here, because a high frequency signal is not transmitted through the wiring of the reset signal, a less radiation noise is generated, and therefore, an exogenous noise becomes a problem. The exogenous noise often proceeds in from an outside of the circuit board. Also, the shield pattern may sometimes be omitted from the wiring of the reset signal due to a limitation of a manufacturing cost or a limitation when the wiring is arranged on the circuit board. Therefore, in the present embodiment, the shield pattern of only upper and lower layers of the wiring of the reset signal is checked.

When the wiring to be protected is the wiring of the reset signal (Yes at step S43), the determination unit 32 proceeds to step S45 described below. Meanwhile, when the wiring to be protected is not the wiring of the reset signal (No at step S43), the determination unit 32 performs a shield pattern check process for checking a shield pattern of the same wiring layer (step S44). Then, the determination unit 32 performs a check of a shield pattern of the upper and lower layers (step S45). In checking the shield pattern of the upper and lower layers, the determination unit 32 obtains an overlapped region between the wiring to be protected and a region of a wiring having a ground characteristic, which is connected to a ground of the upper and lower layers. Then, when the overlapped region exists at a predetermined ratio or more, the determination unit 32 determines that is shielded, whilst when the overlapped region exists at a ratio less than the predetermined ratio, the determination unit 32 determines that it is insufficiently shield. This predetermined ratio can be properly determined in accordance with a design condition, and as an example, it is 80%.

The presentation unit 33 determines, as a result of the determination by the determination unit 32, whether there is a portion determined to be insufficiently shielded (step S46). If there is a portion determined to be insufficiently shielded (Yes at step S46), the presentation unit 33 presents the portion on the circuit board determined to be insufficiently shielded (step S47), and proceeds to step S40. Meanwhile, when there is no portion determined to be insufficiently shielded (No at step S46), the presentation unit 33 proceeds to step S40.

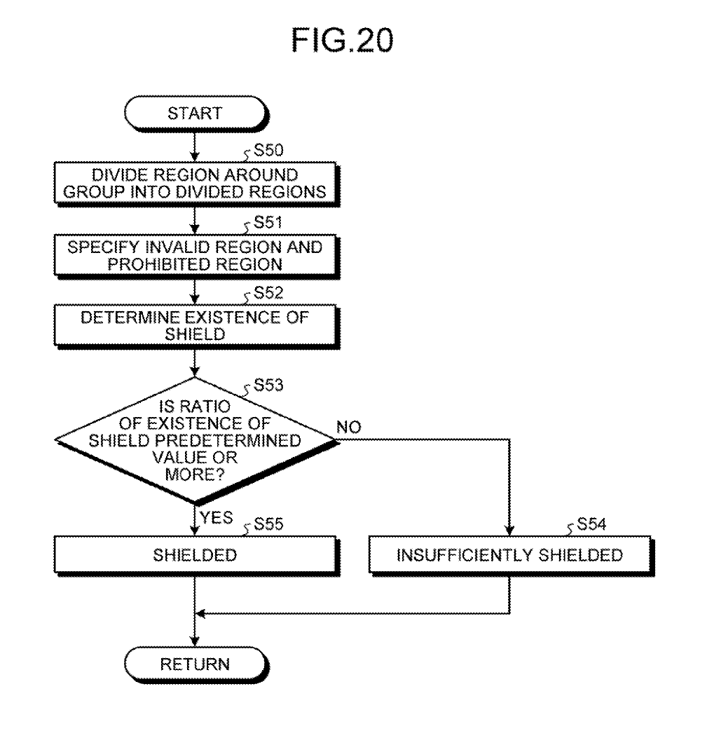

Next, a flow of the shield pattern check process for checking the shield pattern of the same wiring layer according to the present embodiment will be described. FIG. 20 is a flowchart illustrating a procedure of the shield pattern check process. This shield pattern check process is executed upon being called by step S44 of the inspection process illustrated in FIG. 19.

As illustrated in FIG. 20, the division unit 31 divides, for each of groups into which the wirings to be protected are grouped, a region around the group on the circuit board into a plurality of divided regions (step S50). The determination unit 32 specifies an invalid region and a prohibited region as regions where it is hard to arrange a shield (step S51). The determination unit 32 determines the existence of a shield for each divided region with having divided regions in the invalid region and the prohibited region as a region not to be determined (step S52).

As a result of the determination, the determination unit 32 determines whether the ratio of the divided regions determined there is a shield is the ratio input to the input region 43 on the setting screen 40 or more (step S53). When the ratio of the divided regions determined there is a shield is not the ratio input to the input region 43 on the setting screen 40 or more (No at step S53), the determination unit 32 determines that the group of the wirings to be protected is insufficiently shielded (step S54), and terminates the process. Meanwhile, when the ratio of the divided regions determined there is a shield is the ratio input to the input region 43 on the setting screen 40 or more (Yes at step S53), the determination unit 32 determines that the group of the wirings to be protected is shielded (step S55), and terminates the process.

### Effects of First Embodiment

The shield inspection device 10 according to the present embodiment groups closely arranged wirings to be protected from among a plurality of wirings to be protected by means of a shield and arranged on the circuit board. Then, the shield inspection device 10 according to the present embodiment divides, for each of the grouped groups, a region around the group on the circuit board into a plurality of divided regions. The shield inspection device 10 according to the present embodiment determines the existence of a shield for each divided region. Therefore, according to the shield inspection device 10 of the present embodiment, for each group, a region between the wirings to be protected within the group is excluded from a region to be determined regarding the existence of a shield, whereby an inspection of the electro-magnetic compatibility of the wiring to be protected can be promptly performed. Also, according to the shield inspection device 10 of the present embodiment, the existence of a shield is determined for each divided region obtained by dividing the region around the group, whereby the inspection of the shield state can be performed without comparing complicated forms.

Further, the shield inspection device 10 according to the present embodiment obtains, with respect to each of the wirings to be protected, the ratio of being parallel with an adjacent other wiring to be protected with a gap less than a predetermined distance, and groups the wirings to be protected in such a way that the wirings to be protected having the ratio of the predetermined value or more can belong to the same group. Therefore, according to the shield inspection device 10 of the present embodiment, the wirings to be protected having a similar wiring pattern can be grouped into the same group. The wirings such as a bus wiring through which the same type of data is transmitted are arranged in a similar wiring pattern. Therefore, according to the shield inspection device 10 of the present embodiment, by grouping the wirings to be protected having the similar wiring pattern into the same group, the wirings through which the same type of data is transmitted can be grouped into the same group.

Further, the shield inspection device 10 according to the present embodiment divides a region at a predetermined distance outside from the wiring to be protected belonged to the group and positioned at an outermost side of the group into a plurality of divided regions. Therefore, according to the shield inspection device 10 of the present embodiment, a region to be inspected of a shield can be divided into divided regions for each group. By dividing the region into such divided regions, the inspection of the shield state can be performed without comparing complicated forms.

Further, the shield inspection device 10 according to the present embodiment determines that there is a shield when a conductor or a power line connected to a ground exists on the divided region, whilst the shield inspection device 10 determines that there is no shield when no conduct or power line exists. Therefore, according to the shield inspection device 10 of the present embodiment, whether it is shielded can be properly determined for each divided region.

Further, the shield inspection device 10 according to the present embodiment performs determination with having a divided region on the circuit board on which predetermined parts are arranged as a region not to be determined. Therefore, according to the shield inspection device 10 of the present embodiment, whether it is shielded can be determined excluding the region where a shield is not applicable.

Further, the shield inspection device 10 according to the present embodiment presents, as a result of the determination, a portion on the circuit board determined to be insufficiently shielded. Therefore, according to the shield inspection device 10 of the present embodiment, the user can recognizes the portion determined to be insufficiently shielded, thereby taking measures to correct the insufficient shield by arranging a shield and the like.

### [b] Second Embodiment

An embodiment in relation to an apparatus of the disclosure has been described. However, the present invention can be implemented in various different forms other than the above-described embodiment. Therefore, hereinafter, another embodiment included in the present invention will be described.

For example, in the above-described embodiment, a case has been described in which a plurality of closely arranged data wirings is grouped. However, the apparatus of the disclosure is not limited to the case. Closely arranged wirings to be protected other than the data wirings can be grouped.

Further, in the above-described embodiment, a case has been described in which the inspection of the shield pattern of the same wiring layer and the inspection of the shield pattern of the upper and lower layers are sequentially performed. However, the apparatus of the disclosure is not limited to the case. For example, the inspection of the shield pattern of the same wiring layer and the inspection of the shield pattern of the upper and lower layer can be divided into separate programs and the inspections may be separately performed.

Also, in the above-described embodiment, a case has been described in which a group of the wirings to be protected is selected, a region around the selected group of the wirings to be protected is divided, and the inspection of the existence of a shield is repeated. However, the apparatus of the disclosure is not limited to the case. For example, with respect to all of the groups, the regions around all of the groups are divided into divided regions and the inspection of the existence of a shield may be performed.

Dispersion and Integration

Further, the configuration elements of each of the illustrated devices are not necessarily physically configured as illustrated. That is, a specific embodiment of dispersion/integration of each of the devices is not limited to the illustrated embodiment, and a part or the whole thereof can be configured by being functionally or physically dispersed/integrated in an arbitrary unit in accordance with various loads or a usage. For example, each processing unit of the grouping unit 30, the division unit 31, the determination unit 32, and the presentation unit 33 of the shield inspection device 10 may be properly integrated. Further, the process of each processing unit may be properly dispersed into processes of a plurality of processing units. Also, the grouping unit 30, the division unit 31, the determination unit 32, and the presentation unit 33 may be included in separate apparatuses, and may be worked together by a network connection, so that the function of the above-described shield inspection device 10 may be realized.

A shield inspection program

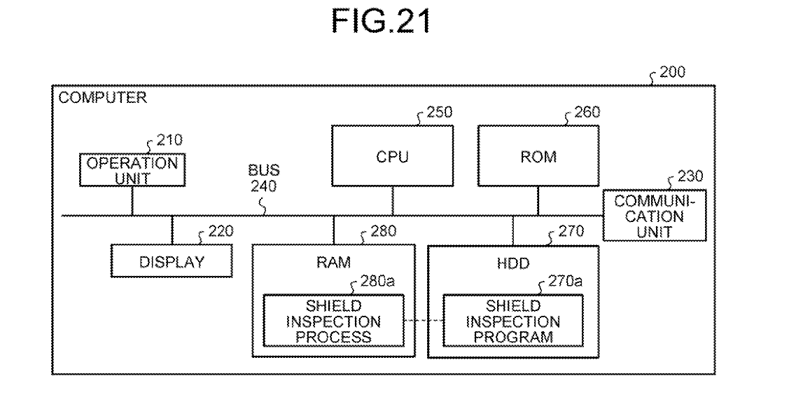

Further, the various processes described in the above embodiment can be realized by causing a prepared program to be executed by a computer such as a personal computer or a workstation. Therefore, an example of a computer that executes a shield inspection program having a similar function to the above-described embodiment will be herein described with reference to FIG. 21.

FIG. 21 is a diagram for describing an example of a computer that executes a shield inspection program. As illustrated in FIG. 21, a computer 200 includes an operation unit 210, a display 220, and a communication unit 230. Further, this computer 200 includes a CPU 250, a ROM 260, an HDD 270, and a RAM 280. Each of these units 210 to 280 is connected via a bus 240.

A shield inspection program 270a that exerts similar functions to the grouping unit 30, the division unit 31, the determination unit 32, and the presentation unit 33 are stored in the HDD 270 in advance. This shield inspection program 270a can be properly integrated or dispersed in a similar manner to each configuration element illustrated in the first embodiment. That is, all of the data stored in the HDD 270 are not necessarily always stored in the HDD 270, and only the data necessary for a process may just be stored in the HDD 270.

Then, the CPU 250 reads out the shield inspection program 270a from the HDD 270 and expands the program in the RAM 280. Therefore, as illustrated in FIG. 21, the shield inspection program 270a functions as a shield inspection process 280a. This shield inspection process 280a properly expands various data read out from the HDD 270 in a region on the RAM 280 allocated to itself, and executes various processes based on the expanded various data. The shield inspection process 280a includes the processes executed in the grouping unit 30, the division unit 31, the determination unit 32, and the presentation unit 33, for example, includes the grouping process, the parallel ratio calculation process, the inspection process, and the shield pattern check process as illustrated in FIGS. 17 to 20. For example, the shield inspection process 280a executes, with respect to the CAD data 20, the grouping process, the parallel ratio calculation process, the inspection process, and the shield pattern check process when a predetermined operation that instructs an inspection of a shield is performed. That is, the shield inspection process 280a executes a similar operation to the grouping unit 30, the division unit 31, the determination unit 32, and the presentation unit 33. Note that all of the processing units virtually realized in the CPU 250 do not necessarily always operate in the CPU 250, and only the processing units necessary for the process may just be virtually realized.

Note that the above-described shield inspection program 270a is not necessarily stored in the HDD 270 or the ROM 260 in advance. For example, the program is stored in a flexible disk to be inserted into the computer 200, what is called, a “transportable physical medium” such as an FD, a CD-ROM, a DVD disk, a magneto-optical disk, and an IC card. Then, the computer 200 may obtain each program from this transportable physical medium and executes the program. Also, each program may be stored in other computer, server device, and the like connected to the computer 200 via a public line, the internet, a LAN, a WAN, and the like, and the computer 200 may obtain each program therefrom and executes the program.

According to a shield inspection device disclosed by the present invention, existence of a shield is determined for each divided region obtained by dividing a region around a group, and therefore, a region between the wirings to be protected in the group can be excluded from a check, whereby the inspection of the electro-magnetic compatibility of the wiring to be protected can be promptly performed.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A shield inspection device comprising:
a grouping unit that groups a closely arranged wirings to be protected from among a plurality of wirings to be protected by means of a shield and arranged on a circuit board;
a division unit that divides, for each of groups into which the wirings to be protected are grouped by the grouping unit, a region around the group on the circuit board into a plurality of divided regions; and
a determination unit that determines existence of a shield for each of the divided regions divided by the division unit.

2. The shield inspection device according to claim 1, wherein the grouping unit obtains, with respect to each of the wirings to be protected, a ratio of being parallel with an adjacent other wiring to be protected with a gap less than a predetermined distance, and groups the wirings to be protected having the ratio of a predetermined value or more into a same group.

3. The shield inspection device according to claim 1, wherein the division unit divides a region at a predetermined distance outside from a wiring to be protected belonged to a group and positioned at an outermost side of the group into a plurality of divided regions.

4. The shield inspection device according to claim 1, wherein the determination unit determines that there is a shield when a conductor connected to a ground or a power line exists on the divided region, and the determination unit determines that there is not a shield when the conductor connected to a ground or the power line does not exist.

5. The shield inspection device according to claim 1, wherein the determination unit performs determination with having a divided region within a region on the circuit board on which predetermined parts are arranged as a region not to be determined.

6. The shield inspection device according to claim 1, further comprising:
a presentation unit that presents a portion determined to be insufficiently shielded on the circuit board as a result of determination by the determination unit.

7. A computer-readable recording medium having stored therein a program for causing a computer to execute a process for a shield inspection processing, the process comprising:
grouping closely arranged wirings to be protected from among a plurality of wirings to be protected by means of a shield and arranged on a circuit board;
dividing, for each of groups into which the wirings to be protected are grouped, a region around the group on the circuit board into a plurality of divided regions; and
determining existence of a shield for each of the divided regions.

8. A shield inspection method comprising:
grouping, by a computer, closely arranged wirings to be protected from among a plurality of wirings to be protected by means of a shield and arranged on a circuit board;
dividing, by the computer, for each of groups into which the wirings to be protected are grouped, a region around the group on the circuit board into a plurality of divided regions; and
determining, by the computer, existence of a shield for each of the divided regions.
